(19) United States
(12) Patent Application Publication
(10) Pub. No.: US 2022/0320028 A1
(43) Pub. Date: Oct. 6, 2022

(54) SEMICONDUCTOR PACKAGING STRUCTURE, METHOD, DEVICE AND ELECTRONIC PRODUCT

(71) Applicant: Yibu Semiconductor Co., Ltd., Shanghai (CN)

(72) Inventor: Weiping LI, Shanghai (CN)

(21) Appl. No.: 17/707,953

(22) Filed: Mar. 30, 2022

Related U.S. Application Data
(63) Continuation-in-part of application No. 17/693,358, filed on Mar. 12, 2022.

(30) Foreign Application Priority Data
Apr. 1, 2021 (CN) 202110352884.7

(51) Int. Cl. H01L 23/00; H01L 25/10; H01L 21/56

(52) U.S. Cl. CPC H01L 24/24; H01L 25/105; H01L 24/73; H01L 24/32; H01L 21/56; H01L 24/19; H01L 2224/73267; H01L 2224/32225; H01L 2924/182; H01L 2924/186; H01L 2924/1511; H01L 2924/15153; H01L 2924/15788; H01L 2224/24137; H01L 2924/3511; H01L 2924/37001; H01L 2924/301

(57) ABSTRACT

The application provides a semiconductor packaging structure, a semiconductor packaging method, a semiconductor packaging device and an electronic product. The semiconductor packaging structure comprises a substrate, at least one packaged component, a redistribution layer and a passivation layer. The substrate has at least one groove and the at least one packaged component is fixed in the at least one groove in one-to-one correspondence. Each packaged component is separated from a corresponding groove, in which the package component is disposed, by insulating materials. The at least one packaged component has first bonding pads on at least one active surface facing away from the substrate and are flush. The redistribution layer is formed using wafer fabrication process over the at least one active surface. The substrate includes a semiconductor material or insulating material with a thermal expansion coefficient that is the same as or similar to that of a base semiconductor material in the packaged component.

### CROSS REFERENCE TO RELATED APPLICATIONS

The present application claims the benefit of priority under the Paris Convention to Chinese Patent Application No. 202110352884.7, filed Apr. 1, 2021, entitled “Semiconductor Packaging Structure, Method, Device and Electronic Product,” and is a continuation-in-part of U.S. patent application Ser. No. 17/693,358, filed Mar. 12, 2022, which claims the benefit of priority under the Paris Convention to Chinese Patent Application No. 202110269375.8, filed Mar. 12, 2021, entitled “Semiconductor Packaging Structure, Method, Device and Electronic Product,” and Chinese Patent Application No. 202110272185.1, filed Mar. 12, 2021, entitled “Semiconductor Packaging Structure, Method, Device and Electronic Product,” each of which is incorporated by reference herein in its entirety. The present application is related to co-pending U.S. patent application Ser. No. 17/693,357, filed Mar. 12, 2022, entitled “Semiconductor Packaging Structure, Method, Device and Electronic Product,” which is incorporated herein by reference in its entirety.

### FIELD OF THE INVENTION

The present application relates to the technical field of semiconductor fabrication, in particular to a semiconductor packaging structure, a semiconductor packaging method, a packaged semiconductor device and an electronic product including same.

### BACKGROUND

In a typical semiconductor packaging process, a component (e.g., a die, also referred to as die) needs to be packaged, generally by fixing the component on a substrate, a frame (e.g., lead frame) or an interposer, and then packaging the component in a series of processes such as interconnect formation and molding encapsulation, to obtain a packaged semiconductor device. The packaged semiconductor device is then assembled with (e.g., electrically connected to and mechanically secured to) other packaged semiconductor devices.

### SUMMARY

Certain embodiments are directed to providing a semiconductor packaging structure, a semiconductor packaging method, a packaged semiconductor device and an electronic product including same.

In some embodiments, a semiconductor package structure comprises a substrate, at least one first packaged component, at least one second packaged component, a redistribution layer, and a passivation layer. In some embodiments, formed in the substrate are at least one first groove corresponding, respectively, to the at least one first packaged component, and at least one second groove, corresponding, respectively, to the at least one second packaged component. In some embodiments, the at least one first packaged component is fixed in the at least one first groove in a one-to-one corresponding manner, the second packaged components are fixed in the at least one second groove in a one-to-one corresponding manner, the first packaged component is in a bare chip state, and the second packaged component is in a packaged state and is provided with an exposed second electrode structures.

In some embodiments, the active surface of the at least one first packaged component faces away from the substrate, each first packaged component is separated from the corresponding first groove where the first packaged component is located by one or more insulating materials, each second packaged component is separated from a corresponding second groove where the second packaged component is located by one or more insulating materials, the at least one first packaged component is provided with first bonding pads on at least one active surface of the first packaged component, surfaces of the first bonding pads facing away from the substrate and surfaces of the second electrode structures facing away from the substrate are flush.

In some embodiments, the redistribution layer is formed using wafer fabrication processes on one side of the packaged components facing away from the substrate and includes a plurality of second pads on a first surface of the redistribution layer and a plurality of third pads on a second surface, opposite to the first surface, of the redistribution layer. The first bonding pads are respectively and electrically connected to a first subset of the second pads, the second electrode structures are respectively and electrically connected with a second subset of the second pads, and the redistribution layer is further provided with routing wires for electrically connecting the second pads and the third pads and routing wires for electrically connecting certain second pads and certain second electrode structures.

In some embodiments, the passivation layer is positioned on one side of the redistribution layer facing away from the substrate.

In some embodiments, the substrate is formed of a semiconductor material or an insulating material that has the same or similar thermal expansion coefficient as that of a base semiconductor material in the at least one first packaged component.

In some embodiments, a semiconductor packaging method comprises forming at least one first groove and at least one second groove in a substrate, fixing at least one first packaged component in the at least one first groove in a one-to-one correspondence manner, and fixing at least one second packaged component in the at least one second groove in a one-to-one correspondence manner. In some embodiments, the at least one first packaged component is in a bare chip state, and the at least one second packaged component is in a packaged state and has exposed second electrode structures. In some embodiments, the active surface of the at least one first packaged component faces away from the substrate, each first packaged component is separated from the corresponding first groove where the first packaged component is located by one or more insulating materials, each second packaged component is separated from a corresponding second groove where the second packaged component is located by one or more insulating materials, the at least one first packaged component is provided with first bonding pads on at least one active surface of the first packaged component, surfaces of the first bonding pads facing away from the substrate and surfaces of the second electrode structures facing away from the substrate are flush.

In some embodiments, the semiconductor packaging method further comprises forming a planar surface exposing the first bonding pads and the second electrode structure;

In some embodiments, the semiconductor packaging method further comprises forming a redistribution layer using wafer fabrication processes on one side of the packaged components facing away from the substrate. The redistribution layer includes a plurality of second pads on a first surface of the redistribution layer and a plurality of third pads on a second surface, opposite to the first surface, of the redistribution layer. The first bonding pads are respectively and electrically connected to a first subset of the second pads, the second electrode structures are respectively and electrically connected with a second subset of the second pads, and the redistribution layer is further provided with routing wires for electrically connecting the second pads and the third pads and routing wires for electrically connecting certain second pads and certain second electrode structures

In some embodiments, the semiconductor packaging method further comprises forming a passivation layer.

In some embodiments, the substrate is formed of a semiconductor material or an insulating material, and the substrate has the same or similar thermal expansion coefficient as that of the semiconductor material in the at least one packaged component.

In some embodiments, a semiconductor device comprising the foregoing semiconductor packaging structure is provided.

In some embodiments, an electronic product comprising the foregoing semiconductor device is provided.

The embodiments provide several benefits, as compared with conventional packaging technologies, as discussed in the following.

Because the thermal expansion coefficients of the semiconductor material in the packaged component and the substrate are equal or close (for example, the two are made of a same semiconductor material), after the packaging is completed, and the thermal expansion coefficient of at least one insulating material in the redistribution layer is equal or close to that of the insulating material in the first packaged element, after the packaging is completed, the warpage of the semiconductor packaging structure generated due to changes in temperature is relatively small, resulting in improved yield and electrical and mechanical reliability of the semiconductor device. Also, in some embodiments, the semiconductor substrate provides better heat dissipation than the molding material of conventional packaging forms.

Further, the redistribution layer is formed by semiconductor fabrication processes (FAB processes). Thus, not only is the fabrication processes mature, but also the line width in the redistribution layer is thinner and the line distance is smaller, resulting in higher interconnection density in the redistribution layer and smaller size of the resulting semiconductor packaging structure.

The first packaged component is in a bare chip state, and the second packaged component is an element which is packaged. The semiconductor packaging structure realizes primary packaging of a first packaged component and secondary packaging of a second packaged component, and realizes interconnection between the first packaged component and the second packaged component. This reduces the process steps for assembling two types of packaged components.

### BRIEF DESCRIPTION OF THE DRAWINGS

FIGS. 1a and 1b are schematic structural diagrams of two semiconductor package structures, respectively, according to some embodiments.

FIG. 2 is a flow chart illustrating a semiconductor packaging method according to some embodiments.

FIGS. 3a to 3f are schematic product states of the semiconductor package structure shown in FIG. 1a at different stages of packaging in accordance with some embodiments.

FIGS. 4a to 4f are schematic product states of the semiconductor package structure shown in FIG. 1B at different stages of packaging in accordance with some embodiments.

In the drawings, 1 denotes a substrate; H1 denotes first groove; H2 denotes second groove; 111 or 112 denotes an insulating material; 3 denotes a redistribution layer; 31 denotes a second pad; 32 denotes a third pad; 33 denotes routing traces; 4 denotes a passivation layer; 5 denotes an electrode structure; 21a denotes a second packaged component; 22a or 23a denotes a first packaged component; 211a denotes a second electrode structure; 221a or 231a denotes a first pad.

### DETAILED DESCRIPTION OF THE EMBODIMENTS

In this application, it will be understood that terms such as “including” or “having,” or the like, are intended to indicate the presence of the disclosed features, numbers, steps, acts, components, parts, or combinations thereof, but do not preclude the presence or addition of one or more other features, numbers, steps, acts, components, parts, or combinations thereof.

It should be noted that the embodiments and features of the embodiments described herein may be combined with each other without conflict. Some embodiments will be described in detail below with reference to examples shown in the attached drawings.

Some embodiments provide a semiconductor package structure, which comprises a substrate, at least one first packaged component, at least one second packaged component, a redistribution layer, and a passivation layer. In some embodiments, at least one first groove and at least one second groove are formed in the substrate, the at least one first packaged component is fixed in the at least one first groove in one-to-one correspondence, the at least one second packaged component is fixed in the at least one second groove in one-to-one correspondence, each first packaged component is separated from a corresponding first groove, in which the first package component is disposed, by insulating materials, and each second packaged component is separated from a corresponding second groove, in which the second package component is disposed, by insulating materials. In some embodiments, the at least one first packaged component is in a bare chip state and has at least one active surface facing away from the substrate and first bonding pads on the at least one active surface, the at least one second packaged component is in a packaged state and is provided with exposed second electrode structures, and surfaces of the first bonding pads facing away from the substrate and surfaces of the second electrode structures facing away from the substrate are flush.

In some embodiments, the redistribution layer is formed on one side of the at least one first packaged component and the at least one second packaged component facing away from the substrate, the redistribution layer has a first surface formed with a plurality of second bonding pads and a second surface opposite to the first surface and formed with a plurality of third bonding pads, a first subset of the second bonding pads are in electrical contact with respective ones of the first bonding pads, a second subset of the second bonding pads are in electrical contact with respective ones of the second electrode structures, and the redistribution layer further includes routing wires to provide electrical interconnection between the second bonding pads and the third pads and routing wires to provide electrical interconnection between the second bonding pads and the second electrode structures. In some embodiments, the redistribution layer is formed using wafer fabrication processes.

In some embodiments, the passivation layer is positioned on one side of the redistribution layer facing away from the substrate.

In some embodiments, the substrate includes a semiconductor material or an insulating material having a thermal expansion coefficient that is the same as or similar to that of a base semiconductor material in the at least one first packaged component.

For example, the base semiconductor material in the substrate is the same as the semiconductor material in the first packaged component.

In the present application, two materials are said to have the same or approximately the same thermal expansion coefficients when an absolute value of the ratio of the difference between the thermal expansion coefficients to the smaller of the thermal expansion coefficients is less than 9.

For example, a base semiconductor material in the packaged component is silicon or gallium arsenide or gallium nitride or silicon carbide, and the material of the substrate is a glass material. The coefficients of thermal expansion of these materials are close (e.g., being in the same order of magnitude).

In some embodiments, the first packaged component is disposed in a first recess formed in the substrate, the second packaged component is disposed in a second recess formed in the substrate, and the first packaged component and the second packaged component are covered by the redistribution layer. The base material in the substrate is the same as the base material in the first packaged component.

The first packaged component is in a bare chip state, and the second packaged component is an element which is packaged. The semiconductor packaging structure realizes primary packaging of a first packaged component and secondary packaging of a second packaged component, and realizes interconnection between the first packaged component and the second packaged component. This reduces the process steps for assembling two types of packaged components and also enables a greater density of interconnections.

The second packaged component is packaged in the form of a chip package, a ceramic package, or the like. The second packaged component may be, for example, a chip resistor, a chip multilayer ceramic capacitor, or the like, or may be another component already in a packaged state.

The shape and position of each second electrode structure of the same second packaged component are not limited in the present application, as long as the second electrode structures have flush surfaces, so as to realize coplanarity with the surfaces of the first bonding pads of the first packaged component.

By referring to two elements as having “the same semiconductor material” in this application, it is to indicate that they include semiconductor materials of the same chemical composition, e.g., both are formed of silicon material, or both are formed of gallium arsenide material, etc. However, these semiconductor materials are not limited to having the same uniformity, purity, density, crystalline state, or the like.

Because the thermal expansion coefficients of the first packaged component and the substrate are the same or similar, after the packaging is finished, the warpage of the semiconductor device caused by temperature change is relatively small and the yield of the semiconductor packaging structure and the electrical and mechanical reliability are improved. Also, in some embodiments, the semiconductor substrate dissipates heat better than the molding material of conventional packaging forms.

Further, the semiconductor packaging structure realizes secondary packaging of the second packaged component and interconnection between the first packaged component and the second packaged component, resulting in higher level of integration, while reducing the process steps for assembling the two types of packaged elements.

Further, since the redistribution layer can be formed by existing semiconductor fabrication processes (FAB processes, or wafer fabrication processes). The fabrication processes for forming the redistribution is mature, and the wire width and the wire distance in the redistribution layer can be thinner, so that the interconnection density is higher, and the size of the resulting semiconductor packaging structure is smaller.

For example, the traces in the redistribution layer are formed by wafer fabrication processes including deposition, lithography, and etching, and the insulating material in the redistribution layer is formed by wafer fabrication processes including deposition (e.g., chemical vapor deposition or CVD).

In some embodiments, the coefficients of thermal expansion of the insulating material in the first package component and the insulating material in the redistribution layer are the same or similar.

For example, the insulating material in the redistribution layer and the insulating material in the first package component both comprise silicon dioxide.

The thermal expansion characteristics of the redistribution layer and the first packaged element are therefore closer, which is further advantageous for preventing warpage of the semiconductor package structure.

When the redistribution layer and the first packaged element both comprise the same insulating material, the fabrication facilities for forming the first packaged element may also be used to form the redistribution layer. This further reduces the complexity of the fabrication processes.

In some embodiments, the at least one first packaged component includes multiple first packaged components equal in thickness, and the at least one first groove includes multiple first grooves equal in depth.

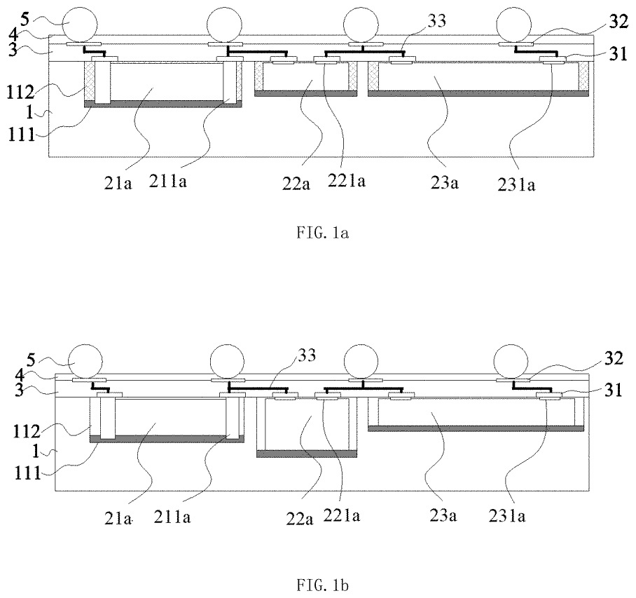

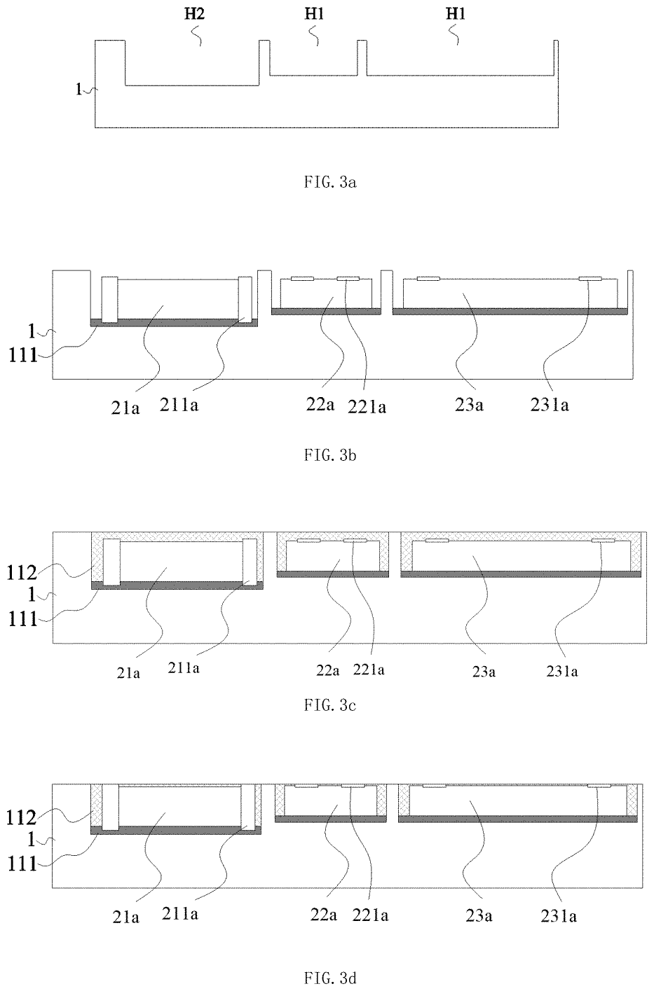

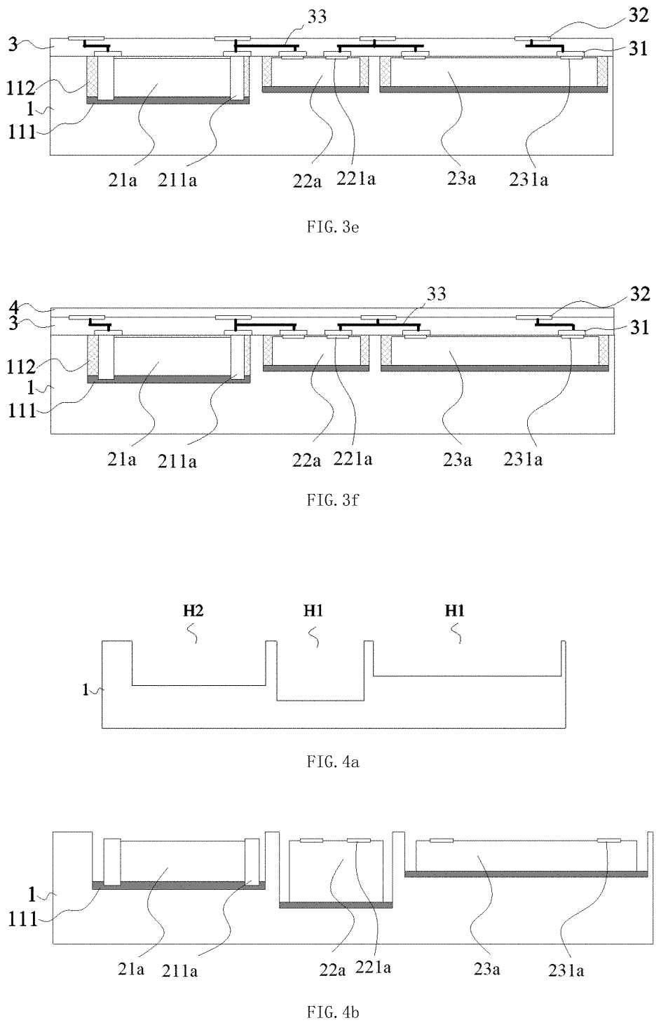

Referring to FIGS. 1a and 3a, the thicknesses of the first packaged components 22a and 23a are equal, and the depths of the first grooves H1 are equal.

In some embodiments, the first packaged component 22a and the first packaged component 23a may be packaged components of the same type or packaged components of different types. Since the thicknesses of the first packaged component 22a and the first packaged component 23a are equal, each first groove 10 can be formed using the same grooving (e.g., etching) process.

If the initial thicknesses of these first packaged components are not uniform, they may be made equal by a thinning process.

In some embodiments, even if the initial thicknesses of these first packaged components 22a, 23a are equal, their thicknesses can be reduced and made equal by a thinning process. In this manner, the groove depth of the recess 10 formed in the substrate 1 can be reduced.

Since the second packaged component 21a is in an encapsulated state, its external dimensions are relatively fixed. The depth of the second recess is largely predetermined and the adjustable margin is relatively small. It is preferred that a relatively thin second packaged component be added to the semiconductor package structure.

In some embodiments, the at least one first packaged component includes at least two first packaged components, and the thicknesses of at least two first packaged components are not equal, wherein the depths of at least two first grooves are different, so that the upper surfaces of the first bonding pads of the first packaged components are flush.

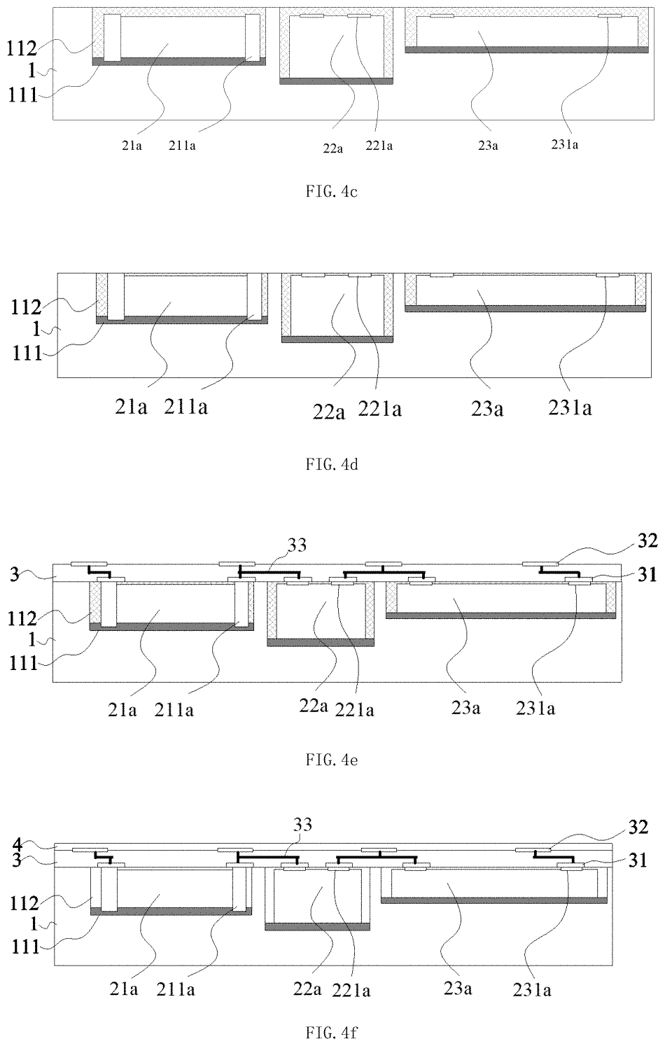

Referring to FIGS. 1B and 4a, the thicknesses of the first packaged component 22a and the first packaged component 23a are not equal, and the depths of the first grooves H1 are not equal. The first packaged component 22a is thicker and, correspondingly, is located at a greater depth in the first recess H1.

The first groove H1 and the second groove H2 may be formed to different depths by controlling a grooving process such as step etching or secondary etching.

In some embodiments, after the passivation layer covers the third bonding pads above the redistribution layer, the semiconductor packaging structure can be used as a product for independent sale.

In some embodiments, referring to FIGS. 1a and 1b, the semiconductor package structure further includes electrode structures 5 on a side of the passivation layer 4 facing away from the substrate 1. Via holes (not shown) can be opened from a side of the passivation layer 4 opposite to the side of the passivation layer facing the third pad 32. The electrode structures 5 correspond, respectively, to the third pads 32, and are respectively and electrically connected to the corresponding third pads 32 through respective via holes.

Specifically, a first electrode structure 5 includes, for example, an Under Bump Metal (UBM) covering a third pad, and a solder ball located above the under-bump metal. The first electrode structure may also be a Pad formed over the third Pad.

In some embodiments, each first packaged component is separated from the groove bottom of a corresponding first groove by an insulating adhesive layer, and each second packaged component is separated from the groove bottom of a corresponding second groove by an insulating adhesive layer. For example, the first or second packaged component is fixed by the insulating adhesive layer, which also serves as insulation between the first or second packaged component and the groove bottom of the first or second groove.

In some embodiments, the first packaged component is separated from the side of the first recess by a cured resin material (e.g., epoxy) or an inorganic insulating material; the second packaged component is separated from the side of the second recess by a cured resin material (e.g., epoxy) or an inorganic insulating material. The gaps between the packaged components and the recesses in which they are located may be filled and cured with a resin material or an inorganic insulating material (e.g., silicon dioxide) may be deposited into the gaps.

The redistribution layer comprises at least one layer of metal traces and through holes for connecting different layers of metal traces (if multiple layers of metal traces are included), the metal traces and the second bonding pads, and/or the metal traces and the third bonding pads. The routings in the redistribution layer can realize the interconnection of the second pads and the third pads, the interconnection of the second pads and the second electrode structures, and the interconnection of certain second pads and other second pads.

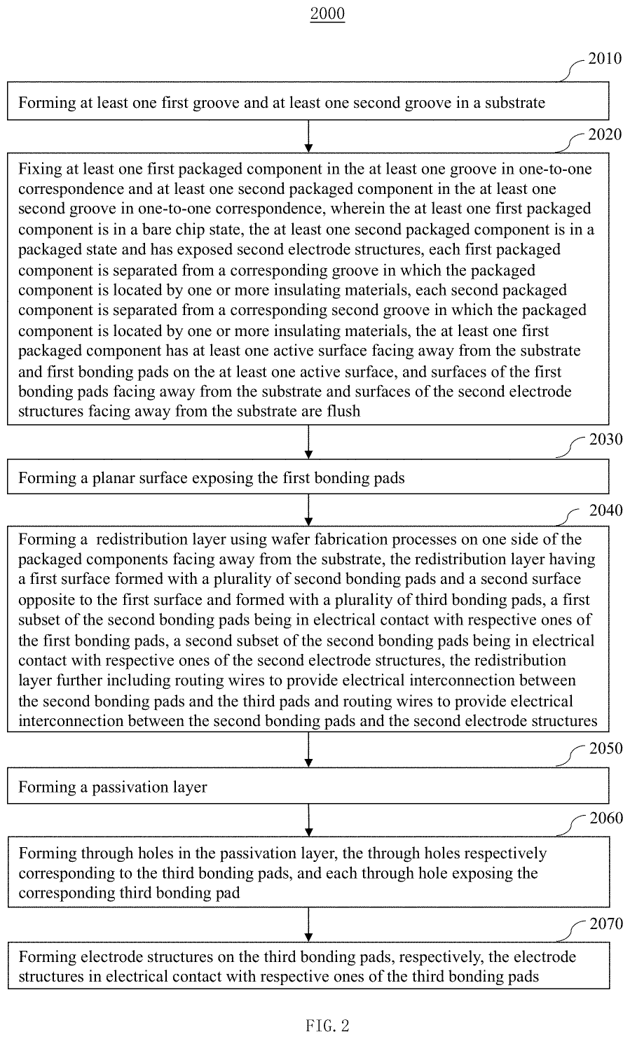

Referring to FIG. 2, some embodiments also provide a semiconductor packaging method 2000. The packaging method 2000 can be used to manufacture the semiconductor packaging structure provided by some embodiments. The semiconductor packaging method 2000 includes steps 2010-2050.

Step 2010—forming at least one first groove and at least one second groove in a substrate.

Step 2020—fixing at least one first packaged component in the at least one groove in one-to-one correspondence and at least one second packaged component in the at least one second groove in one-to-one correspondence. In some embodiments, the at least one first packaged component is in a bare chip state, the at least one second packaged component is in a packaged state and has exposed second electrode structures, each first packaged component is separated from a corresponding groove in which the packaged component is located by one or more insulating materials, each second packaged component is separated from a corresponding second groove in which the packaged component is located by one or more insulating materials, the at least one first packaged component has at least one active surface facing away from the substrate and first bonding pads on the at least one active surface, and surfaces of the first bonding pads facing away from the substrate and surfaces of the second electrode structures facing away from the substrate are flush.

Step 2030—forming a planar surface exposing the first bonding pads and the second electrode structures.

Step 2040—forming a redistribution layer using wafer fabrication processes, the redistribution layer having a first surface formed with a plurality of second bonding pads and a second surface opposite to the first surface and formed with a plurality of third bonding pads, a first subset of the second bonding pads being in electrical contact with respective ones of the first bonding pads, a second subset of the second bonding pads being in electrical contact with respective ones of the second electrode structures, the redistribution layer further including routing wires to provide electrical interconnection between the second bonding pads and the third pads and routing wires to provide electrical interconnection between the second bonding pads and the second electrode structures.

Step 2050—forming a passivation layer.

In some embodiments, the substrate includes a semiconductor material or an insulating material, and a thermal expansion coefficient of the substrate is the same as or similar to that of a base semiconductor material in the at least one first packaged component.

For example, the semiconductor material in the substrate is the same as the semiconductor material in the at least one first packaged component.

As another example, the semiconductor material in the packaged component is silicon or gallium arsenide or gallium nitride or silicon carbide, and the material of the substrate is a glass material.

Because the thermal expansion coefficients of the semiconductor material and the substrate in the first packaged component is the same or similar, the warpage of the semiconductor packaging structure caused by temperature change is relatively small after the packaging is finished, and the yield of the semiconductor packaging structure and the electrical and mechanical reliability are improved.

Also, the thermal conductivity of semiconductor materials or glass material is higher than that of conventional molding compounds, so the heat dissipation of the semiconductor package structure made using the method 2000 is better than conventional semiconductor packages.

Further, the redistribution layer is formed by semiconductor fabrication processes (FAB processes). For example, processes such as deposition, photolithography, etching, etc., may be used to form traces and electrodes in the redistribution layer, and a layer of insulating material may be formed by deposition. Thus, not only is the fabrication processes mature, but also the line width in the redistribution layer is thinner and the line distance is smaller, resulting in higher interconnection density in the redistribution layer and smaller size of the resulting semiconductor packaging structure.

For example, the traces in the redistribution layer can be formed using wafer fabrication processes including deposition, lithography, and etching, and the insulating material in the redistribution layer can be formed using wafer fabrication processes including deposition.

In some embodiments, the coefficients of thermal expansion of the insulating material in the first package component and the insulating material in the redistribution layer are the same or similar or close (e.g., within the same order of magnitude of each other).

For example, the insulating material in the redistribution layer and the insulating material in the first package component both comprise silicon dioxide.

Since the redistribution layer and the first packaged element both contain insulating materials having the same or similar thermal expansion coefficients, the thermal expansion characteristics of the redistribution layer and the first packaged element are closer, which is further beneficial for preventing the warping of the semiconductor packaging structure.

In some embodiments, the packaging method 2000 further comprises steps 2060 and 2070.

Step 2060—forming at least one through hole on the passivation layer. The through holes correspond to the third bonding pads one to one, and the through holes expose the corresponding third bonding pads.

Step 2070—forming first electrode structures over respective ones of the third bonding pads and in electrical contact with respective ones of the third bonding pads.

In some embodiments, the at least one first packaged component includes multiple first packaged components, and the at least one first groove includes multiple first grooves equal in depth, and the packaging method 2000 further comprises thinning at least some of the first packaged components so that the multiple first packaged components have equal depth.

In some embodiments, the at least one first packaged component includes at least two first packaged components of unequal thicknesses, and the at least one first groove includes at least two first grooves of unequal depths such that upper surfaces of the first bonding pads of the at least two first packaged components are flush.

In some embodiments, fixing the at least one first packaged component in one-to-one correspondence in the at least one first groove, respectively, comprises forming an insulating adhesive layer at a bottom surface of each first groove, affixing each first packaged component on the insulating adhesive layer in a corresponding first groove, reserving a gap between the first packaged component each side surface of the corresponding first groove, and filling the gap between the first packaged component and each side surface of the corresponding first groove with an insulating material.

In some embodiments, filling the gap between the first packaged component and each side surface of the corresponding first groove with an insulating material comprises injecting and curing a resin material between the first packaged component and the corresponding first groove side surface, or depositing an inorganic oxide insulating material in the gap between the first packaged component and the corresponding first groove side surface.

In some embodiments, fixing the at least one second packaged component in one-to-one correspondence in the at least one second groove, respectively, comprises forming an insulating adhesive layer at a bottom surface of each second groove, affixing each second packaged component on the insulating adhesive layer in a corresponding second groove, reserving a gap between the second packaged component each side surface of the corresponding second groove, and filling the gap between the second packaged component and each side surface of the corresponding second groove with an insulating material.

In some embodiments, filling the gap between the second packaged component and each side surface of the corresponding second groove with an insulating material comprises injecting and curing a resin material between the second packaged component and the corresponding second groove side surface, or depositing an inorganic oxide insulating material in the gap between the second packaged component and the corresponding second groove side surface.

In some embodiments, forming a planar surface exposing the first bonding pads and the second electrode structure comprises removing portions of the insulating material and the substrate material that are higher than the first bonding pads and the second electrode structure using a grinding process and following with surface treatment.

In some embodiments, the method further comprises forming a plurality of via holes on the passivation layer. In some embodiments, the via holes correspond to the third bonding pads one to one, and the via holes expose the corresponding third bonding pads before being filled with a conductive material to form conductive vias. The method further comprises forming first electrode structures on and in electrical contact with the third bonding pads through the conductive vias.

In some embodiments, the substrate has sufficient area to allow a number of first grooves and second grooves to be formed therein. Method 2000 further comprises dicing the substrate to obtain a plurality of semiconductor packaging structures. At least one semiconductor packaging structure comprises at least one first packaged component, at least one second packaged component, a first groove in which the first packaged component is dispose, a second groove in which the second packaged component is disposed, a redistribution layer electrically connected with the first packaged component and the second packaged component, and a passivation layer over the redistribution layer.

In some embodiments, the second packaged component includes a chip on package or a ceramic package.

In some embodiments, referring to FIGS. 3a to 3f and FIG. 1a, the semiconductor packaging method 2000 can be implemented as follows.

In step 2010, referring to FIG. 3a, a plurality of first grooves H1 and at least one second groove H2 are formed in a substrate 1 by an etching process, wherein the depths of a plurality of first grooves H1 are equal but different from the depths of the at least one second groove H2.

In step 2020, referring to FIG. 3b, an insulating adhesive layer 111 is formed at the groove bottoms of the first and second grooves H1 and H2.

Referring to FIG. 3b, first packaged components 22a and 23a are respectively placed in the first grooves H1, at least one second packaged component 21a is placed in the second groove H2, and the first packaged components 22a and 23a and the second packaged component 21a are all adhered to the insulating adhesive 111. In some embodiments, the first bonding pads 211a of the first packaged component 22a and the first bonding pads 231a of the first packaged component 23a face upward, the thicknesses of the first packaged component 22a and the first packaged component 23a are equal, and the upper surfaces of the first bonding pads 221a and 231a and the second electrode structure 211a are flush. The first packaged component 22a, 23a and the second packaged component 21a are spaced from the side walls of the recesses H1, H2.

Referring to FIG. 3c, the insulating material 112 is filled and cured into the first grooves H1 and the second groove H2. For example, a liquid epoxy resin is dropped into the gap between the first grooves H1 and the first packaged or to-be-packaged components 22a, 23a, a liquid epoxy resin is dropped into the gap between the second groove H2 and the second packaged or to-be-packaged component 21a, and the epoxy resin is cured by heating. Alternatively, an inorganic insulating material (e.g., silicon dioxide) is deposited into the gaps between the first grooves H1 and the first packaged components 22a, 23a, and an inorganic insulating material is deposited into the gaps between the second groove H2 and the second packaged component 21a.

In step 2030, referring to FIG. 3d, portions of the insulating material 112 higher than the first bonding pads 221a, 231a and the second electrode structure 211a and portions of the substrate material higher than the first bonding pads 221a, 231a and the second electrode structure 211a are removed by grinding, which is followed with a surface treatment process such as chemical cleaning, polishing, etc. to obtain a flat surface exposing the first bonding pads 221a, 231a and the second electrode structure 211a.

In step 2040, referring to FIG. 3e, a redistribution layer 3 is formed on the flat surface, the second electrodes 31 of the redistribution layer 3 are electrically contacted with the first bonding pads 221a and 231a and the second electrode structures 211a, respectively, and the third electrodes 32 of the redistribution layer 3 are interconnected with the second electrodes 31.

Specifically, for example, in step 2040, the second electrodes 31 may be patterned by sputtering or electroplating, and patterning processes such as photolithography, etching, and cleaning. Afterwards, an insulating material layer (for example, a silicon dioxide layer) is formed by an FAB process such as deposition. Afterwards, via holes exposing the second electrodes 31 are formed in the insulating material layer. Afterwards, traces 33 connecting the second electrodes 31 are formed by sputtering or electroplating, and patterning processes. Afterwards, another insulating material layer is deposited; a layer of routing 33 and a layer of insulating material are formed again; then, via holes exposing the lower traces 33 are formed in the newly obtained insulating material layer. Finally, the pattern of the third electrodes 32 is obtained through processes of sputtering, electroplating and patterning.

In some embodiments, the patterning process may be used to form the pattern of the second pad 31 first, before forming the insulating material layer, the via hole in the insulating material layer to expose the second pad 31, and the pattern of the first layer traces 33.

The redistribution layer can also be prepared by those skilled in the art according to conventional technologies.

In the above manner, the processes for fabricating the redistribution layer 3 are common with some of the processes for fabricating bare chips. There can be multiple layers of traces 33 in the redistribution layer. The line width and the line pitch of the traces or wirings in the redistribution layer 3 can be made very small.

In step 2050, referring to FIG. 3f, a passivation layer 4 is formed on the redistribution layer 3. The passivation layer 4 may be made of silicon nitride (sin), polyimide (polyimide), or the like. The passivation layer 4 serves to protect the elements therebelow.

In step 2060, referring to FIG. 1a, via holes are etched in the passivation layer 4 to expose the respective third electrodes 32, and, in step 2070, first electrode structures 5 are formed on the third electrodes 32. The first electrode structures 5 include, for example, Under Bump Metal (UBM) on the third electrodes 32 and solder balls on the under-bump metal. The first electrode structures 5 may also be in the form of bonding pads.

In some embodiments, referring to FIGS. 4a to 4f and FIG. 1B, the semiconductor packaging method 2000 can be implemented as follows.

In step 2010, referring to FIG. 4a, a plurality of first grooves H1 and at least one second groove H2 are formed in the substrate 1 by controlling a grooving process (e.g., step etching or multiple etching), wherein the depths of grooves are different.

In step 2020, referring to FIG. 4b, an insulating adhesive layer 111 is formed on the groove bottoms of the first grooves H1 and the at least one second groove H2.

Referring to FIG. 4b, the first packaged component 22a and the first packaged component 23a are respectively placed in the first grooves H1, the at least one second packaged component 21a is placed in the at least one second groove H2, and the first packaged components 22a, 23a and the at least one second packaged component 21a are all adhered on the insulating adhesive 111. In some embodiments, the first bonding pads 221a of the first packaged component 22a and the first bonding pads 231a of the first packaged component 23a face upward, the upper surfaces of the first bonding pads 221a, 231a and the second electrode structure 211a are flush, the thicknesses of the first packaged components 22a, 23a and the second packaged component 21a are not equal, and the groove depths of the grooves in which the first packaged components 22a, 23a and the second packaged component 21a are located are not equal.

Referring to FIG. 4c, the insulating material 112 is filled and cured into the first groove H1 and the second groove H2. For example, a liquid epoxy resin is dropped into the gap between the first groove H1 and the first package-to-be-packaged component 22a, 23a, and into the gap between the second groove H2 and the second package-to-be-packaged component 21a, and the epoxy resin is cured by heating.

In step 2030, referring to FIG. 4d, portions of the insulating material higher than the first bonding pads 221a, 231a and the second electrode structure 211a, and portions of the substrate material higher than the first bonding pads 221a, 231a and the second electrode structure 211a, are removed by grinding, and then a surface treatment process such as chemical cleaning, polishing, etc. is performed to obtain a flat surface exposing the first bonding pads 221a, 231a and the second electrode structure 211a.

In step 2040, referring to FIG. 4e, a redistribution layer 3 is formed on the flat surface, the second pads 31 of the redistribution layer 3 are respectively in electrical contact with the first bonding pads 221a and 231a and the second electrode structures 211a, and the third pads 32 of the redistribution layer 3 are interconnected with the second pads 31. The redistribution layer 3 at least includes traces 33, vias connecting the traces 33 and the second pads 31, and vias connecting the traces 33 and the third pads 32.

Specifically, the second electrodes 31 may be patterned by sputtering or electroplating, and patterning processes such as photolithography, etching, and cleaning. Afterwards, an insulating material layer (for example, a silicon dioxide layer) is formed by an FAB process such as deposition, and via holes exposing the second electrodes 31 are formed in the insulating material layer. Afterwards, traces 33 connecting the second electrodes 31 are formed by sputtering or electroplating, and patterning processes. Afterwards, another insulating material layer is deposited; then, via holes exposing the lower traces 33 are formed in the newly obtained insulating material layer, and finally, the pattern of the third electrodes 32 is obtained through sputtering or electroplating and patterning processes.

In the above manner, the processes for fabricating the redistribution layer are common with some of the processes for fabricating bare chips. The redistribution layer includes at least one layer of traces 33.

In step 2050, referring to FIG. 4f, a passivation layer 4 is formed on the redistribution layer 3. The passivation layer 4 may be made of silicon nitride (sin), polyimide (polyimide), or the like. The passivation layer 4 serves to protect the elements therebelow.

In step 2060, referring to FIG. 1B, vias are etched in the passivation layer 4 to expose the respective third electrodes 32, and, in step 2070, first electrode structures 5 are formed on the third electrodes 32. The first electrode structures 5 include, for example, Under Bump Metal (UBM) over the third electrodes 32 and solder balls over the under-bump metal. The first electrode structures 5 may also be bonding Pads.

Some embodiments further provide a semiconductor device including the foregoing semiconductor package structure. The semiconductor package structure may be further processed, for example, to be combined with other semiconductor packages into an assembly or module.

Some embodiments further provide an electronic product including the foregoing semiconductor device. The electronic product can be any of various electronic products such as mobile phones, computers, servers, smartwatches, and the like.

Due to the improvement of the stability of the semiconductor packaging structure, the stability of the semiconductor devices and the electronic products is correspondingly improved.

The embodiments in the present application are described in a progressive manner, and the same and similar parts among the embodiments can be referred to each other, and each embodiment focuses on the differences from the other embodiments.

The protective scope of the present application is not limited to the above-described embodiments, and it is apparent that various modifications and variations can be made to the present application by those skilled in the art without departing from the scope and spirit of the present application. It is intended that the present application also include such modifications and variations as come in the scope of the appended claims and their equivalents.

What is claimed is:

1. A semiconductor package structure, comprising: a substrate, packaged components, a redistribution layer, and a passivation layer, the packaged components including at least one first packaged component and at least one second packaged component, wherein:
at least one first groove and at least one second groove are formed in the substrate;
the at least one first packaged component is fixed in the at least one first groove in one-to-one correspondence;
the at least one second packaged component is fixed in the at least one second groove in one-to-one correspondence;
each first packaged component is separated from a corresponding first groove, in which the first package component is disposed, by insulating materials;
each second packaged component is separated from a corresponding second groove, in which the second package component is disposed, by insulating materials;
the at least one first packaged component is in a bare chip state and has at least one active surface facing away from the substrate and first bonding pads on the at least one active surface;
the at least one second packaged component is in a packaged state and is provided with exposed second electrode structures;
surfaces of the first bonding pads facing away from the substrate and surfaces of the second electrode structures facing away from the substrate are flush;
the redistribution layer is formed using wafer fabrication processes on one side of the packaged components facing away from the substrate;
the redistribution layer has a first surface formed with a plurality of second bonding pads and a second surface opposite to the first surface and formed with a plurality of third bonding pads;
a first subset of the second bonding pads are in electrical contact with respective ones of the first bonding pads;
a second subset of the second bonding pads are in electrical contact with respective ones of the second electrode structures;
the redistribution layer further includes routing wires to provide electrical interconnection between the second bonding pads and the third pads and routing wires to provide electrical interconnection between the second bonding pads and the second electrode structures;
the passivation layer is positioned on one side of the redistribution layer facing away from the substrate; and
the substrate includes a semiconductor material or an insulating material having a thermal expansion coefficient that is the same as or similar to that of a base semiconductor material in the at least one first packaged component.

2. The semiconductor package structure of claim 1, wherein the semiconductor material in the substrate is the same as the base semiconductor material in the at least one first packaged component, and wherein the base semiconductor material in the at least one packaged component includes silicon, gallium arsenide, gallium nitride or silicon carbide.

3. The semiconductor package structure of claim 1, wherein the at least one first packaged component includes multiple first packaged components equal in thickness, and the at least one first groove includes multiple first grooves equal in depth.

4. The semiconductor package structure of claim 1, wherein the at least one first packaged component includes at least two first packaged components of unequal thicknesses, and wherein the at least one first groove includes at least two first grooves of unequal depths such that upper surfaces of the first bonding pads of the at least two first packaged components are flush.

5. The semiconductor package structure according to claim 1, further comprising first electrode structures on a side of the passivation layer facing away from the substrate, wherein via holes are formed in the passivation layer, the first electrode structures corresponding to the third pads one by one and being electrically connected to the corresponding third pads through the via holes.

6. The semiconductor package structure of claim 1, wherein the substrate includes a glass material, and wherein each first packaged component is separated from the bottom of a corresponding groove by an insulating adhesive layer.

7. The semiconductor package structure of claim 1, wherein each first packaged component is separated from side surfaces of a corresponding first groove by a cured resin material or an inorganic insulating material, and wherein each second packaged component is separated from side surfaces of a corresponding second recess by a cured resin material or an inorganic insulating material.

8. The semiconductor package structure of claim 1, wherein the redistribution layer includes conductive traces separated from each other by an insulating material having a same or approximately the same thermal expansion coefficient as an insulating material in the at least one first packaged component.

9. The semiconductor package structure of claim 1, wherein the wafer fabrication processes include deposition of at least one layer of silicon dioxide.

10. The semiconductor package structure of claim 1, wherein each second packaged component is a chip-on-chip package or a ceramic package.

11. A semiconductor packaging method, comprising:
forming at least one first groove and at least one second groove in a substrate;
fixing at least one first packaged component in the at least one groove in one-to-one correspondence and at least one second packaged component in the at least one second groove in one-to-one correspondence, wherein the at least one first packaged component is in a bare chip state, the at least one second packaged component is in a packaged state and has exposed second electrode structures, each first packaged component is separated from a corresponding groove in which the packaged component is located by one or more insulating materials, each second packaged component is separated from a corresponding second groove in which the packaged component is located by one or more insulating materials, the at least one first packaged component has at least one active surface facing away from the substrate and first bonding pads on the at least one active surface, and surfaces of the first bonding pads facing away from the substrate and surfaces of the second electrode structures facing away from the substrate are flush;
forming a planar surface exposing the first bonding pads and the second electrode structures;
forming a redistribution layer using wafer fabrication processes on one side of the packaged components facing away from the substrate, the redistribution layer having a first surface formed with a plurality of second bonding pads and a second surface opposite to the first surface and formed with a plurality of third bonding pads, a first subset of the second bonding pads being in electrical contact with respective ones of the first bonding pads, a second subset of the second bonding pads being in electrical contact with respective ones of the second electrode structures, the redistribution layer further including routing wires to provide electrical interconnection between the second bonding pads and the third pads and routing wires to provide electrical interconnection between the second bonding pads and the second electrode structures; and
forming a passivation layer;
wherein the substrate includes a semiconductor material or an insulating material, and a thermal expansion coefficient of the substrate is the same as or similar to that of a base semiconductor material in the at least one first packaged component.

12. The semiconductor packaging method of claim 11, wherein the semiconductor material in the substrate is the same as the base semiconductor material in the at least one first packaged component, and wherein the base semiconductor material in the at least one packaged component includes silicon, gallium arsenide, gallium nitride or silicon carbide.

13. The semiconductor packaging method of claim 11, wherein forming a redistribution layer using wafer fabrication processes comprises:
forming the plurality of second bonding pads using processes including sputtering or electroplating depositing a layer of an insulating material over the plurality of second bonding pads;
forming through vias in first layer of insulating material; and
forming conductive traces over the layer of insulating material using processes including sputtering or electroplating, each conductive trace being electrically connected to at least one of the plurality of second bonding pads by at least one of the through vias.

14. The semiconductor packaging method of claim 13, wherein the layer of insulating material includes silicon dioxide.

15. The semiconductor packaging method of claim 11, wherein the at least one first packaged component includes multiple packaged components equal in thickness, and the at least one first groove includes multiple first grooves equal in depth.

16. The semiconductor packaging method of claim 11, wherein the at least one first packaged component includes at least two first packaged components of unequal thicknesses, and the at least one first groove includes at least two first grooves of unequal depths such that upper surfaces of the first bonding pads of the at least two first packaged components are flush.

17. The semiconductor packaging method of claim 11, wherein fixing the at least one first or second packaged component in one-to-one correspondence in the at least one first or second groove, respectively, comprises:
forming an insulating adhesive layer at a bottom surface of each first or second groove;
affixing each first or second packaged component on the insulating adhesive layer in a corresponding first or second groove, reserving a gap between the first or second packaged component each side surface of the corresponding first or second groove; and
filling the gap between the first or second packaged component and each side surface of the corresponding first or second groove with an insulating material.

18. The semiconductor packaging method of claim 17, wherein filling the gap between the first or second packaged component and each side surface of the corresponding first or second groove with an insulating material comprises:
injecting and curing a resin material between the first or second packaged component and the corresponding first or second groove side surface, or depositing an inorganic oxide insulating material in the gap between the first or second packaged component and the corresponding first or second groove side surface.

19. The semiconductor packaging method of claim 11, wherein forming a planar surface exposing the first bonding pads and the second electrode structure comprises:
removing portions of the insulating material and the substrate material that are higher than the first bonding pads and the second electrode structure using a grinding process and following with surface treatment.

20. The semiconductor packaging method of claim 11, further comprising:
forming a plurality of via holes in the passivation layer, wherein the via holes correspond, respectively, to the third bonding pads and exposing the corresponding third bonding pads; and
forming first electrode structures in electrical contact, respectively, with the third pads.
